(19) United States
(12) Patent Application Publication
(10) Pub. No.: US 2022/0352431 A1
(43) Pub. Date: Nov. 3, 2022

(54) SPECTRUM PACKAGING STRUCTURE AND MANUFACTURING METHOD THEREFOR

(71) Applicant: DURA-CHIP (NANTONG) LIMITED, Nantong (CN)

(72) Inventors: Zhijiang SUN, Nantong (CN); Shuchang WANG, Nantong (CN); Lu WU, Nantong (CN)

(21) Appl. No.: 17/866,552

(22) Filed: Jul. 18, 2022

Related U.S. Application Data
(63) Continuation of application No. PCT/CN2021/072449, filed on Jan. 18, 2021.

(30) Foreign Application Priority Data
Jan. 20, 2020 (CN) 202010064142.X
Mar. 20, 2020 (CN) 202010201100.6
Mar. 25, 2020 (CN) 202020391101.7
Jun. 28, 2020 (CN) 202010596034.7

(51) Int. Cl. H01L 33/50; H01L 25/075; H01L 33/44; H01L 33/58

(52) U.S. Cl. CPC H01L 33/504; H01L 25/0753; H01L 33/44; H01L 33/58; H01L 2933/0025; H01L 2933/005; H01L 2933/0041

(57) ABSTRACT

The present disclosure provides a spectrum packaging structure and a method for manufacturing the spectrum packaging structure. The spectrum packaging structure includes a substrate, a luminous body arranged on the substrate and an outer packaging layer for packaging the luminous body on the substrate. The luminous body includes a first CSP chip and at least one second CSP chip. The first CSP chip includes a purple light chip and a first packaging layer coating an outer surface of the purple light chip, the first packaging layer is a phosphor layer containing blue phosphor particles. The second CSP chip includes a blue light chip and a second packaging layer coating an outer surface of the blue light chip, the second packaging layer is a phosphor layer containing red phosphor particles and/or yellow-green phosphor particles.

### CROSS-REFERENCE TO RELATED APPLICATIONS

This application is a continuation of PCT patent application PCT/CN2021/072449 filed on Jan. 18, 2021, which claims all benefits accruing from China Patent Application Nos. 202010064142.X, filed on Jan. 20, 2020, 202010201100.6, filed on Mar. 20, 2020, 202010596034.7, filed on Jun. 28, 2020, and 202020391101.7, filed on Mar. 25, 2020, in the China National Intellectual Property Administration, the contents of which are hereby incorporated by reference.

### TECHNICAL FIELD

The present disclosure relates to a spectrum packaging structure and a method for manufacturing the spectrum packaging structure.

### BACKGROUND

The current demand in LED (Light Emitting Diode) lighting has changed from initial brightness and color temperature of light to a color and color rendering effect of light, as people begin to pursue quality of light and a comfortable and healthy experience. The concept of “solar spectrum” frequently appears.

Compared with the color of light of a conventional LED and a full-spectrum LED, the color of light of a solar spectrum LED is the most natural. So that the color of light of a solar spectrum LED can better restore a true color of an object, be comfortable and does not hurt eyes.

Conventional technical solutions have the following main problems.

A chip is fixed to a substrate by a solder paste, a die bonding adhesive, or a silver glue, etc. A mixed phosphor powder is generally sprayed around a top surface of the chip, and there is a problem of secondary absorption for the mixed phosphor powder. Different kind of fluorescent powder has a different optimal excitation wavelength, and using a single wavelength of light to excite the mixed phosphors powder cannot achieve excellent luminous efficiency, due to the optimal excitation wavelength of each kind of fluorescent powder was different, so that an excitation efficiency of a certain kind of fluorescent powder using the single wavelength of light is low. Therefore, when the mixed phosphor powder is used, although a color rendering index is improved, energy loss is large and luminous efficiency is low. The secondary absorption has a great influence on the color rendering index and the luminous efficiency.

However, a current conventional technical solution of simply using violet-blue phosphor powder and a blue light chip to excite red phosphor powder still has a problem of missing a spectrum at 480 nm, and the spectrum at 480 nm has a great influence on regulating human rhythm. Uniformity of color in space distribution of the conventional technical solution is poor, resulting in large color variation and low color saturation. In summary, current conventional packaging solutions cannot achieve a solar-like spectrum or a full spectrum in a real sense.

### SUMMARY

A technical problem to be solved by the present disclosure is to provide a spectrum packaging structure that can effectively increase spectral continuity and improve overall luminous efficiency, and further to provide a method for manufacturing the spectrum packaging structure.

To solve the above technical problem, a technical solution of the present disclosure is described as follows. A spectrum packaging structure includes a substrate, a luminous body and an outer packaging layer. The luminous body is arranged on the substrate, and the substrate is configured for supporting or connected to the luminous body. The luminous body includes a first CSP (Chip Scale Package) chip and at least one second CSP chip. The outer packaging layer is configured for packaging the luminous body on the substrate in total or partially. An innovative feature is as follows. The first CSP chip includes a purple light chip and a first packaging layer coating an outer surface of the purple light chip, and the first packaging layer is a phosphor layer containing blue phosphor particles. The at least one second CSP chip includes a blue light chip and a second packaging layer coating an outer surface of the blue light chip, and the second packaging layer is a phosphor layer containing red phosphor particles and/or yellow-green phosphor particles. By using a plurality of different wavelengths of chips to excite fluorescent powder, it can take into account excitation wavelengths of different kinds of fluorescent powder, that is, it can be achieved that a short-wavelength chip excites short-wavelength fluorescent powder, and a long-wavelength chip excites long-wavelength fluorescent powder. It can make full use of photon energy of the short-wavelength chip to improve excitation efficiency of the blue fluorescent powder, avoid scattered excitation of fluorescent powder of each color and insufficient excitation of the blue fluorescent powder due to lower luminous efficiency of the short-wavelength chip.

The first CSP chip is formed by the blue light chip coated with blue phosphor particles, which can limit a peak wavelength of the purple light to a maximum extent, utilize the purple light chip with maximum efficiency to excite and generate much more long-wavelength blue light near 480 nm, and reduce harmful short-wavelength blue light in a range of 400 nm to 460 nm.

The yellow-green phosphor particles is arranged outside the blue light chip, which can avoid being arranged on the outer packaging layer in total or partially, thus reducing absorption of the light of the blue fluorescent powder excited by the purple light in the outer packaging layer, especially reducing absorption of the blue light at 480 nm by long-wavelength yellow-green fluorescent powder.

The red phosphor particles are arranged outside the blue light chip, and an amount of the red phosphor particles in the outer packaging layer can also be reduced. So that irradiation on the red phosphor particles from short-wavelength fluorescence and medium-wavelength fluorescence can be reduced, thus effectively reducing secondary absorption of cyan fluorescence, blue fluorescence, and green fluorescence. In particular, the excitation efficiency of the cyan fluorescence is low, which can effectively reduce a secondary loss of the cyan fluorescence, thereby improving luminous efficiency and a color rendering index.

Furthermore, emission intensity of the short-wavelength blue light in the second CSP chip can be independently adjusted by the yellow-green phosphor particles and the red phosphor particles in the second CSP chip, so that the beneficial long-wavelength blue light near 480 nm can be used to replace the harmful short-wavelength blue light in a range of 400 nm to 460 nm to a maximum extent.

In the present disclosure, a refractive index of the first packaging layer is defined as n1, a refractive index of the second packaging layer is defined as n2, a refractive index of the outer packaging layer is defined as n3, and n1, n2, and n3 satisfy the following formula: n3≥n1>n2. It is beneficial to control propagation of light in combination with an optical refractive index, so that the blue light excited by the purple light chip in the first CSP chip can enter the second CSP chip as little as possible, and the blue light of 450 nm to 480 nm can be avoided to be absorbed by the yellow-green phosphor particles, especially the blue light around 480 nm. A partial light excited from the first CSP chip and the second CSP chip with some angle can be avoided being totally reflected due to entering the outer packaging layer, the luminous efficiency is higher and a spectral integrity is high.

A peak wavelength of the blue light chip is in a range of 430 nm to 460 nm, and a peak wavelength of the purple light chip is in a range of 390 nm to 420 nm. Other blue phosphor particles with a peak wavelength near 480 nm can also be added to the outer packaging layer to enrich the spectrum of the long-wavelength blue light.

The number of the second CSP chip is one or more. The outer packaging layer further includes red phosphor particles, and a ratio of a weight of the red phosphor particles in the second packaging layer to a total weight of the red phosphor particles in the second packaging layer and the red phosphor particles in the outer packaging layer is in a range of 50% to 80%. In this way, most or even all of the red phosphor particles can be arranged outside the blue light chip, so as to avoid the purple light leaked from the purple light chip being complete absorbed and affecting the spectral integrity. In addition, the luminous body includes at least two second CSP chips, the red phosphor particles are located in the second packaging layer of one of the at least two second CSP chips, and the yellow-green phosphor particles are located in the second packaging layer of the other of the at least two second CSP chips. In this way, during a COB (Chips On Board) package process, it is beneficial to achieve a purpose of quickly spectral adjustment by directly controlling the number of the different at least two second CSP chips.

The one of the at least two second CSP chips including the second packaging layer containing the red phosphor particles is disposed between the first CSP chip and the other of the at least two second CSP chips including the second packaging layer containing the yellow-green phosphor particles. Furthermore, a top surface of the outer packaging layer is provided with a plurality of arc-shaped protrusions and a plurality of arc-shaped recesses arranged at intervals. The plurality of arc-shaped protrusions are located directly above top surfaces of the first CSP chip and the at least one second CSP chip, and the plurality of arc-shaped recesses are located between the first CSP chip and the at least one second CSP chip adjacent to the first CSP chip. The highest point of the plurality of arc-shaped protrusion is not lower than the top surfaces of the first CSP chip and the at least one second CSP chip, and the lowest point of the plurality of arc-shaped recesses is not higher than the top surfaces of the first CSP chip and the at least one second CSP chip. Specifically, a distance between the highest point of the plurality of arc-shaped protrusion and the top surface of the first CSP chip is greater than or equal to 40 micrometers, and a distance between the highest point of the plurality of arc-shaped protrusion and the top surface of the at least one second CSP chip is greater than or equal to 40 micrometers. A distance between the lowest point of the plurality of arc-shaped recesses and the top surface of the first CSP chip is less than or equal to 80 micrometers, and a distance between the lowest point of the plurality of arc-shaped recesses and the top surface of the at least one second CSP chip is less than or equal to 80 micrometers. In this way, an optical waveguide path between the first CSP chip and the at least one second CSP chip can be reduced, thereby reducing absorption of long-wavelength blue light near 480 nm by the second packaging layer. In addition, such arc-shaped structure is conducive to an exit of light beams of the first CSP chip and the at least one second CSP chip, respectively.

The first CSP chip and the at least one second CSP chip are electrically connected to form a circuit, and the first CSP chip and the second CSP chip are connected in series. When the circuit includes a plurality of branches in a parallel connection, a total number of chips in each of the plurality of branches is the same, the number and a connection mode of the first CSP chip in each of the plurality of branches are the same, and the number and a connection mode of the at least one second CSP chip in each of the plurality of branches are the same. Because a change relationship between voltages and current of the purple light chip is very different from that of the blue light chip, when the circuit includes a plurality of branches in a parallel connection, a total number of chips in each of the plurality of branches is the same, the number and a connection mode of the first CSP chip in each of the plurality of branches are the same, and the number and a connection mode of the at least one second CSP chip in each of the plurality of branches are the same, it can avoid instability of color temperature and color point of a synthesized spectrum if power in the circuit is changed.

In another embodiment, the outer packaging layer is a phosphor layer containing red phosphor particles and yellow-green phosphor particles. The red phosphor particles and the yellow-green phosphor particles in the second packaging layer are a long-wavelength red fluorescent powder and a long-wavelength yellow-green fluorescent powder, respectively. The red phosphor particles and the yellow-green phosphor particles in the outer packaging layer are a short-wavelength red fluorescent powder and a short-wavelength yellow-green fluorescent powder, respectively. A peak wavelength of the long-wavelength red fluorescent powder of the second packaging layer is greater than a peak wavelength of the short-wavelength red fluorescent powder of the outer packaging layer, and a peak wavelength of the long-wavelength yellow-green fluorescent powder of the second packaging layer is greater than a peak wavelength of the short-wavelength yellow-green fluorescent powder of the outer packaging layer. The peak wavelength of the long-wavelength red fluorescent powder of the second packaging layer is greater than 640 nm, the peak wavelength of the long-wavelength yellow-green fluorescent powder of the second packaging layer is greater than 540 nm, the peak wavelength of the short-wavelength yellow-green fluorescent powder of the outer packaging layer is less than 540 nm, and the peak wavelength of the short-wavelength red fluorescent powder of the outer packaging layer is less than 640 nm.

The present disclosure further provides a method for smoothly and quickly manufacturing the above spectrum packaging structure. The method includes step (1) of preparing the luminous body, which includes two sub-steps of preparing the first CSP chip and preparing the at least one second CSP chip. The first CSP chip includes the purple light chip and the first packaging layer. The outer surface of the purple light chip is coated by the first packaging layer. The first packaging layer includes blue phosphor particles. The at least one second CSP chip includes the blue light chip and the second packaging layer. The outer surface of the blue light chip is coated by the second packaging layer. The second packaging layer includes red phosphor particles and/or yellow-green phosphor particles, that is, there may be three ways about the second packaging layer: the first way, the second packaging layer can include both red phosphor particles and yellow-green phosphor particles; the second way, the second packaging layer can include only yellow-green phosphor particles; and the third way, the second packaging layer can include only red phosphor particles.

The method further includes step (2) of pre-controlling a color temperature of the luminous body, which includes the following sub-steps: step (a), fixing the first CSP chip and the at least one second CSP chip to corresponding positions of the substrate; step (b), turning on the first CSP chip to obtain a color dot position on a CIE (chromaticity diagram) chromaticity diagram, which is denoted as dot A (X1; Y 1); step (c), turning on the at least one second CSP chip to obtain a color dot position or a mixed color dot position on the CIE chromaticity diagram, which is denoted as dot B (X2; Y2); step (d), turning on the first CSP chip and the at least one second CSP chip to obtain a mixed color dot position on the CIE chromaticity diagram, which is denoted as dot C (X3; Y3).

The method further includes step (3) of preparing the outer packaging layer and step (4) of testing. The step (3) of preparing the outer packaging layer includes coating the outer packaging layer on a surface of the substrate, and adjusting a ratio and/or peak wavelengths of each phosphor particle in the outer packaging layer to make a color dot position of the obtained spectrum packaging structure on the CIE chromaticity diagram coincide with a target color dot position, the target color dot position is denoted as a dot D (X4; Y4). The method has a simple process, strong controllability, obvious cost advantage, and is easy to adjust technical parameters. Furthermore, it is suitable for mass production.

Specifically, the step (3) of preparing the outer packaging layer includes the following two sub-steps.

Firstly, sub-step (3a), according to color temperature requirement of the target spectrum packaging structure, searching for the target color dot position corresponding to the color temperature requirement on Planck locus of the CIE chromaticity diagram, and denoting the target color dot position as the dot D (X4; Y4), and obtaining a specific coordinate value or a coordinate range of a color dot position of dot E (X5; Y5) on the CIE chromaticity diagram by using the dot C (X3; Y3) and the dot D (X4; Y4).

Then, sub-step (3b), adding the blue phosphor particles, the red phosphor particles and/or the yellow-green phosphor particles to a packaging material of the outer packaging layer; and adjusting a ratio and/or peak wavelengths of the blue phosphor particles, the red phosphor particles, and/or the yellow-green phosphor particles to prepare the outer packaging layer according to a specific coordinate value or a coordinate range of a color dot position of dot E (X5; Y5). If the blue phosphor particles are added in the packaging material of the outer packaging layer, determining whether the specific coordinate value or the coordinate range of the dot E (X5; Y5) falls within a color coordinate range corresponding to a range of peak wavelength of the blue phosphor particles firstly. When if it is not within the color coordinate range corresponding to the range of peak wavelength of the blue phosphor particles, adjusting peak wavelengths and a weight ratio of various phosphor particles of the first packaging layer according to the dot A (X1; Y1) and the dot B (X2; Y2), and repeating sub-step (3a) until the specific coordinate value or the coordinate range of the dot E (X5; Y5) falls within the color coordinate range corresponding to the range of peak wavelength of the blue phosphor particles. If the red phosphor particles are added in the packaging material of the outer packaging layer, determining whether the specific coordinate value or the coordinate range of the dot E (X5; Y5) falls within a color coordinate range corresponding to a range of peak wavelength of the red phosphor particles firstly. When if it is not within the color coordinate range corresponding to the range of peak wavelength of the red phosphor particles, adjusting peak wavelengths and a weight ratio of various phosphor particles of the first packaging layer according to the dot A (X1; Y1) and the dot B (X2; Y2) and repeating sub-step (3a) until the specific coordinate value or the coordinate range of the dot E (X5; Y5) falls within the color coordinate range corresponding to the range of peak wavelength of the red phosphor particles.

### BRIEF DESCRIPTION OF THE DRAWINGS

FIG. 1 is a structural schematic diagram of a spectrum packaging structure of the present disclosure.

FIG. 2 is a structural schematic diagram of a spectrum packaging structure in embodiment 1 of the present disclosure.

FIG. 3 is a spectrogram of the spectrum packaging structure in embodiment 1 of the present disclosure.

FIG. 4 is a structural schematic diagram of a spectrum packaging structure in embodiment 2 of the present disclosure.

FIG. 5 is a spectrogram of the spectrum packaging structure in embodiment 2 of the present disclosure.

FIG. 6 is a spatial distribution diagram of color temperature of the spectrum packaging structure in embodiment 2 of the present disclosure.

FIG. 7 is a structural schematic diagram of a spectrum packaging structure in embodiment 3 of the present disclosure.

FIG. 8 is a spectrogram of the spectrum packaging structure in embodiment 3 of the present disclosure.

FIG. 9 is a spatial distribution diagram of color temperature of the spectrum packaging structure in embodiment 3 of the present disclosure.

FIG. 10 is a structural schematic diagram of a spectrum packaging structure in embodiment 4 of the present disclosure.

FIG. 11 is a structural schematic diagram of a spectrum packaging structure in embodiment 5 of the present disclosure.

FIG. 12 is a spectrogram of the spectrum packaging structure in embodiment 5 of the present disclosure.

FIG. 13 is a spatial distribution diagram of color temperature of the spectrum packaging structure in embodiment 5 of the present disclosure.

FIG. 14 is a structural schematic diagram of a spectrum packaging structure in comparative example 1 of the present disclosure.

FIG. 15 is a spectrogram of the spectrum packaging structure in comparative example 1 of the present disclosure.

FIG. 16 is a structural schematic diagram of a spectrum packaging structure in comparative example 2 of the present disclosure.

FIG. 17 is a spectrogram of the spectrum packaging structure in comparative example 2 of the present disclosure.

FIG. 18 is a structural schematic diagram of a spectrum packaging structure in comparative example 3 of the present disclosure.

FIG. 19 is a spectrogram of the spectrum packaging structure in comparative example 3 of the present disclosure.

FIG. 20 is a schematic diagram of a first CSP chip and a second CSP chip electrically connected in a way in the present disclosure.

FIG. 21 is a structural schematic diagram of a spectrum packaging structure in embodiment 6 of the present disclosure.

FIG. 22 is a spectrogram of a first batch of the spectrum packaging structure in embodiment 6 of the present disclosure.

FIG. 23 is a spectrogram of a second batch of the spectrum packaging structure in embodiment 6 of the present disclosure.

FIG. 24 is a spectrogram of a third batch of the spectrum packaging structure in embodiment 6 of the present disclosure.

FIG. 25 is a spectrogram of a fourth batch of the spectrum packaging structure in embodiment 6 of the present disclosure.

FIG. 26 is a distribution diagram of light-exiting angles of a first batch of a solar-like spectrum packaging structure in embodiment 6 of the present disclosure.

FIG. 27 is a test diagram of color temperature uniformity of light-exiting angles of the first batch of the solar-like spectrum packaging structure in embodiment 6 of the present disclosure.

FIG. 28 is a schematic diagram of finding a target color dot in a method for manufacturing the spectrum packaging structure of the present disclosure.

FIG. 29 is an excitation spectrogram of a purple light chip with a peak wavelength of 410 nm and a blue light chip with a peak wavelength of 444 nm exciting a fluorescent powder with a peak wavelength of 480 nm respectively of the present disclosure.

FIG. 30 is an excitation spectrogram and an emission spectrogram of fluorescent powder with a peak wavelength of 512 nm of the present disclosure.

FIG. 31 is an excitation spectrogram and an emission spectrogram of fluorescent powder with a peak wavelength of 626 nm of the present disclosure.

### DETAILED DESCRIPTION

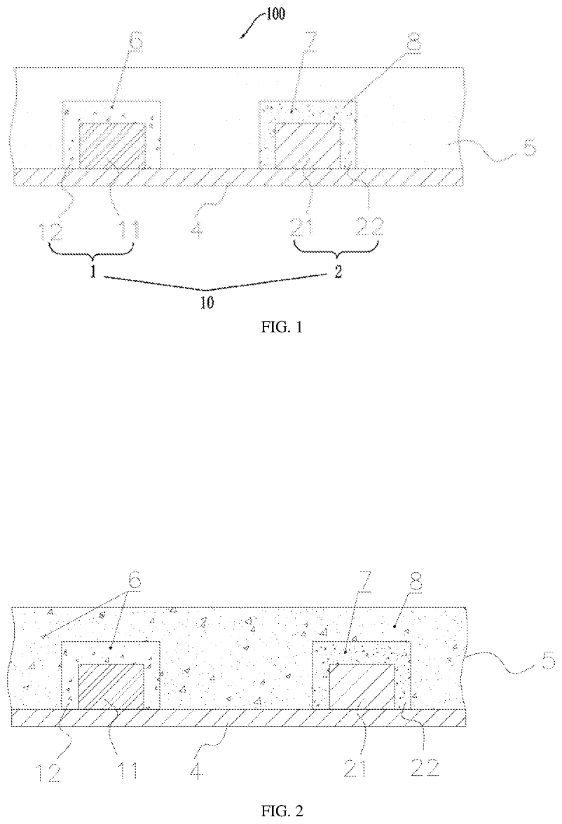

The present disclosure provides a spectrum packaging structure. Referring to FIG. 1, the spectrum packaging structure includes:

a substrate 4;

a luminous body 10 arranged on the substrate 4, wherein the substrate 4 is configured for supporting or connected to the luminous body 10, and the luminous body 10 can include a first CSP chip 1 and at least one second CSP chip 2; and

an outer packaging layer 5 for packaging the luminous body 10 on the substrate 4 in total or partially.

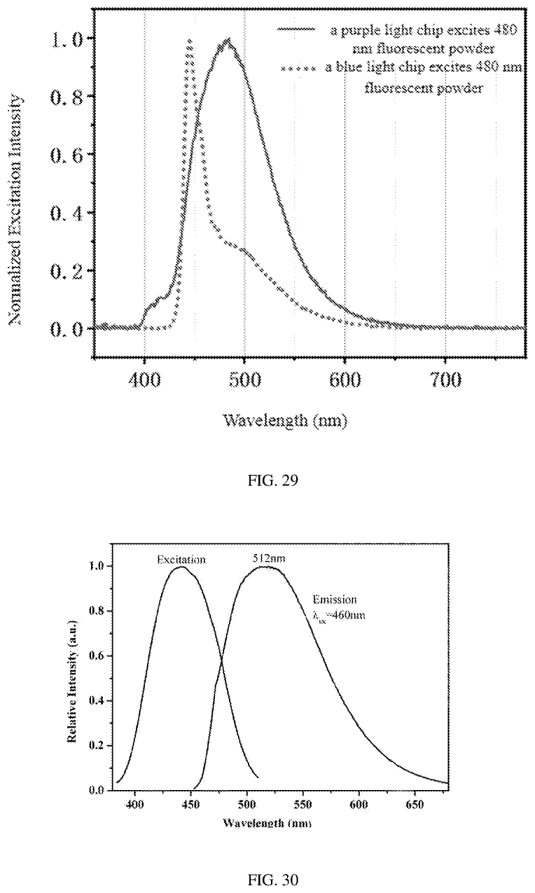

The first CSP chip 1 can include a purple light chip 11 and a first packaging layer 12 coating an outer surface of the purple light chip 11, and a peak wavelength of the purple light chip 11 can be in a range of 390 nm to 420 nm. The first packaging layer 12 can be a phosphor layer containing blue phosphor particles 6 and not containing phosphor particles of other colors. As shown in FIG. 29, the reason for choosing the purple light chip 11 can be excitation efficiency of a purple light chip 11 with a peak wavelength of 410 nm exciting a fluorescent powder with a peak wavelength of about 480 nm can be higher than that of a blue light chip 21 with a peak wavelength of 444 nm exciting a fluorescent powder with a peak wavelength of about 480 nm.

The at least one second CSP chip 2 can include a blue light chip 21, and a second packaging layer 22 coating an outer surface of the blue light chip. The second packaging layer 22 can be a phosphor layer containing red phosphor particles 8 and/or yellow-green phosphor particles 7. And a peak wavelength of the blue light chip 21 can be in a range of 430 nm to 460 nm.

The yellow-green phosphor particles can be located outside the blue light chip 21, which can avoid being arranged on the outer packaging layer 5 in total or partially. Referring to FIG. 30, absorption efficiency of the fluorescent powder with a peak wavelength of 512 nm at 480 nm in the spectrum reaches about 40%, which will reduce spectral intensity of the spectrum in 480 nm, thus reducing absorption of the light of the blue fluorescent powder excited by purple light in the outer packaging layer, especially reducing absorption of blue light at 480 nm by long-wavelength yellow-green fluorescent powder.

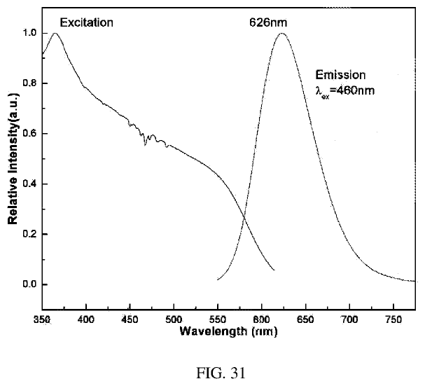

Similarly, as shown in FIG. 31, an absorption spectrum range of the fluorescent powder with a peak wavelength of 626 nm can be wider than that of the fluorescent powder with a peak wavelength of 512 nm, and the absorption efficiency of the fluorescent powder with a peak wavelength of 612 nm band at 480 nm in the spectrum reaches about 55%, which will seriously reduce spectral intensity of the spectrum in 480 nm. So that the red phosphor particles 8 can be located outside the blue light chip 21, and the amount of the red phosphor particles 8 in the outer packaging layer 5 can also be reduced. So that irradiation on the red phosphor particles 8 from short-wavelength fluorescence and medium-wavelength fluorescence can be reduced, thus effectively reducing secondary absorption of cyan fluorescence, blue fluorescence, and green fluorescence. In particular, the excitation efficiency of the cyan fluorescence can be low, which can effectively reduce a secondary loss of the cyan fluorescence, thereby improving luminous efficiency and a color rendering index.

A refractive index of the first packaging layer can be defined as n1, a refractive index of the second packaging layer can be defined as n2, a refractive index of the outer packaging layer 5 can be defined as n3, and n1, n2, and n3 satisfy the following formula: n3≥n1>n2. The purpose can be to control propagation of light in combination with an optical refractive index on a basis of selecting a distribution of phosphor particles with corresponding peak wavelengths in the first CSP chip 1, the second CSP chip 2 and the outer packaging layer 5, respectively. So that the blue light excited by the purple light chip in the first CSP chip can enter the second CSP chip as little as possible, and the blue light of 450 nm to 480 nm can be avoided to be absorbed by the yellow-green phosphor particles, especially the blue light around 480 nm. The light excited from partial angle of the first CSP chip and the second CSP chip can avoid being totally reflected due to entering the outer packaging layer, the luminous efficiency can be higher and a spectral integrity can be high.

Other blue phosphor particles with a peak wavelength near 480 nm can also be added to the outer packaging layer 5 to enrich the spectrum of long-wavelength blue light.

A first implementation route of a technical solution of the present disclosure is provided as below.

The luminous body 10 can include at least one second CSP chips 2. The red phosphor particles 8 can be located in the second packaging layer 22 in total, or, be located in both the second packaging layer 22 and the outer packaging layer 5. A ratio of a weight of the red phosphor particles 8 in the second packaging layer 22 to a total weight of the red phosphor particles 8 in the second packaging layer 22 and the red phosphor particles 8 in the outer packaging layer 5 can be in a range of 50% to 100%. When the red phosphor particles 8 is located in both the second packaging layer 22 and the outer packaging layer 5, the ratio of the weight of the red phosphor particles 8 in the second packaging layer 22 to the total weight of the red phosphor particles 8 in the second packaging layer 22 and the red phosphor particles 8 in the outer packaging layer 5 can be in a range of 50% to 80%. By reducing the amount of the red phosphor particles 8 in the outer packaging layer 5, it can avoid the purple light leaked from the purple light chip 11 being completely absorbed when the purple light passes through the outer packaging layer 5 and prevent affecting the spectral integrity.

Alternatively, most of the red phosphor particles 8 are preferably located in the second packaging layer 22, and a few of the red phosphor particles 8 are located in the outer packaging layer 5, so as to avoid all the red phosphor particles 8 coating on the outer surface of the blue light chip 21, resulting a problem of poor color temperature consistency in different angles. Alternatively, the ratio of the weight of the red phosphor particles 8 in the outer packaging layer 5 to the total weight of the red phosphor particles 8 in the second packaging layer 22 and the red phosphor particles 8 in the outer packaging layer 5 can be in a range of 20% to 30%. The ratio of the weight of the red phosphor particles 8 in the second packaging layer 22 to the total weight of the red phosphor particles 8 in the second packaging layer 22 and the red phosphor particles 8 in the outer packaging layer 5 can be in a range of 70% to 80%.

More specifically, the luminous body 10 can include at least two second CSP chips 2, the red phosphor particles 8 are located in the second packaging layer 22 of one of the at least two second CSP chips 2, and the yellow-green phosphor particles 7 are located in the second packaging layer 22 of the other of the at least two second CSP chips 2. In this way, during a package process such as COB (Chips On Board), it is beneficial to achieve a purpose of spectral adjustment by directly controlling the number of the second CSP chips 2 containing only yellow-green phosphor particles 7 and the number of the second CSP chips 2 containing only red phosphor particles 8.

Furthermore, one second CSP chips 2 including the second packaging layer 22 containing the red phosphor particles 8 can be disposed between the first CSP chip 1 and another second CSP chips 2 including the second packaging layer 22 containing the yellow-green phosphor particles 7. By adjusting a position of the second CSP chips 2 including the second packaging layer 22 containing the red phosphor particles 8, the amount of the blue light of 450 nm to 480 nm excited by the first CSP chip 1 can be reduced to enter the second packaging layer 22 containing yellow-green phosphor particles 7, and avoided to be absorbed by the yellow-green phosphor particles 7 as little as possible, thus improving the integrity of the spectrum.

In the present disclosure, a top surface of the outer packaging layer 5 can optionally be integrally formed with a plurality of arc-shaped protrusions 5a and a plurality of arc-shaped recesses 5b arranged at intervals. The plurality of arc-shaped protrusions 5a can be located directly above top surfaces of the first CSP chip 1 and the second CSP chip 2, and the plurality of arc-shaped recesses 5b can be located between the first CSP chip 1 and the second CSP chip 2 adjacent to the first CSP chip 1. The highest point of the plurality of arc-shaped protrusions 5a can be higher than the top surfaces of the first CSP chip 1 and the at second CSP chip 2, and the lowest point of the plurality of arc-shaped recesses 5b can be lower than the top surfaces of the first CSP chip 1 and the second CSP chip 2. The lowest point of arc-shaped recess 5b needs to be higher than the substrate 4 to protect an upper surface of the substrate 4.

Usually, a distance between the highest point of the plurality of arc-shaped protrusion 5a and the top surface of the first CSP chip 1 can be greater than or equal to 40 micrometers, and a distance between the highest point of the plurality of arc-shaped protrusion 5a and the top surface of the at least one second CSP chip 2 can be greater than or equal to 40 micrometers. A distance between the lowest point of the plurality of arc-shaped recesses 5b and the top surface of the first CSP chip 1 can be less than or equal to 80 micrometers, and a distance between the lowest point of the plurality of arc-shaped recesses 5b and the top surface of the at least one second CSP chip 2 can be less than or equal to 80 micrometers.

Furthermore, projected contours of outer surfaces of the arc-shaped protrusions 5a on the top surfaces of the first CSP chip 1 can completely cover and exceed edges of the top surfaces of the first CSP chip 1, and projected contours of outer surfaces of the arc-shaped protrusions 5a on the top surfaces of the second CSP chip 2 can completely cover and exceed edges of the top surfaces of the second CSP chip 2.

In this way, an optical waveguide path between the first CSP chip 1 and the second CSP chip 2 can be reduced, so that the amount of the blue light emitted from blue phosphor particles excited by the purple light chip 11 can be reduced to enter the second packaging layer 22 containing yellow-green phosphor particles 7. In addition, a surface of the waveguide on the top surface of the outer packaging layer 5 can be damaged, which is not conducive to a formation of continuous total reflection, but conducive to an exit of light beams of the first CSP chip 1 and the second CSP chip 2, respectively. Furthermore, the top surface of the outer packaging layer 5 can be provided with microstructures.

Furthermore, in the packaging structure of the present disclosure, the first CSP chip 1 and the second CSP chip 2 can be electrically connected to form a circuit. The first CSP chip 1 and the second CSP chip 2 can be connected in series. When the circuit includes a plurality of branches in a parallel connection, a total number of chips in each of the plurality of branches can be the same, the number and a connection mode of the first CSP chip 1 in each of the plurality of branches can be the same, and the number and a connection mode of the at least one second CSP chip 2 in each of the plurality of branches can be the same, so as to avoid instability of color temperature and color point of a synthesized spectrum when power in the circuit is changed. FIG. 20 shows one of connection ways, which can include two main branches Z1 and Z2 connected in parallel with each other. The number and the connection mode of the first CSP chips 1 in the two main branches Z1 and Z2 can be the same, and the number and the connection mode of the second CSP chips 2 in the two main branches Z1 and Z2 can be the same. When there are two parallel branches F11 and F12 on the main branch circuit Z1 or Z2, and there are two second CSP chips 2 connected in series on the branch F11, then the branch F12 also has only two second CSP chips 2, and the two second CSP chips 2 on the branch F12 are also connected in series.

### Embodiment 1

The present embodiment 1 is as shown in FIG. 2, a spectrum packaging structure, including:

a first CSP chip 1 disposed on a substrate 4, wherein the first CSP chip 1 can include a purple light chip 11 and a first packaging layer 12 coating an outer surface of the purple light chip 11;

a second CSP chip 2 disposed on the substrate 4, wherein the second CSP chip 2 can include a blue light chip 21 and a second packaging layer 22 coating an outer surface of the blue light chip 21;

an outer packaging layer 5 for packaging the first CSP chip 1 and the second CSP chip 2 on the substrate 4 in total.

A refractive index of the first packaging layer 12 can be defined as n1, a refractive index of the second packaging layer 22 can be defined as n2, a refractive index of the outer packaging layer 5 can be defined as n3, and n1, n2, and n3 can satisfy the following formula: n3≥n1>n2.

In the present embodiment, yellow-green phosphor particles 7 can be only located in the second packaging layer 22.

Blue phosphor particles 6 can be located both in the first packaging layer 12 and the outer packaging layer 5. A ratio of a weight of the blue phosphor particles 6 in the first packaging layer 12 to a total weight of the blue phosphor particles 6 in the first packaging layer 12 and the blue phosphor particles 6 in the outer packaging layer 5 can be 70%, and a ratio of a weight of the blue phosphor particles 6 in the outer packaging layer 5 to a total weight of the blue phosphor particles 6 in the first packaging layer 12 and the blue phosphor particles 6 in the outer packaging layer 5 can be 30%.

Red phosphor particles 8 can be located both in the outer packaging layer 5 and the second packaging layer 22. A ratio of a weight of the red phosphor particles 8 in the outer packaging layer 5 to a total weight of the red phosphor particles 8 in the second packaging layer 22 and the red phosphor particles 8 in the outer packaging layer 5 can be 70%, and a ratio of a weight of the red phosphor particles 8 in the second packaging layer 22 to a total weight of the red phosphor particles 8 in the second packaging layer 22 and the red phosphor particles 8 in the outer packaging layer 5 can be 30%.

In the present embodiment, a peak wavelength of the purple light chip 11 can be in a range of 407 nm to 412 nm, a peak wavelength of the blue light chip 21 can be in a range of 452.5 nm to 455 nm. A peak wavelength of the blue phosphor particles 6 can be 480 nm, a peak wavelength of the yellow-green phosphor particles 7 can be 565 nm, and a peak wavelength of the red phosphor particles 8 can be 660 nm.

In the present embodiment, the first CSP chip 1 can be a purple light chip 11 with a size of 10 mil * 21 mil and a wavelength in a range of 407 nm to 412 nm. The blue phosphor particles 6 can be fluorescent powder with a peak wavelength of 480 nm, a weight ratio of the blue phosphor particles 6 to colloid in the first packaging layer 12 can be 3.5:1, and a refractive index n1 of silica gel can be 1.54.

The second CSP chip 2 can be a blue light chip 21 with a size of 13 mil * 30 mil and a peak wavelength in a range of 452.5 nm to 455 nm. The second packaging layer 22 can be a phosphor layer containing the yellow-green phosphor particles 7 with a peak wavelength of 565 nm and the red phosphor particles 8 with a peak wavelength of 660 nm. The weight ratio of the yellow-green phosphor particles 7 and the red phosphor particles 8 to colloid in the second packaging layer 22 can be 6:1, colloid can include silica gel, and a refractive index n2 of silica gel can be 1.42.

A refractive index n3 of silica gel of the outer packaging layer 5 can be 1.54. The outer packaging layer 5 can be a phosphor layer containing the red phosphor particles 8 with a peak wavelength of 660 nm and the blue phosphor particles 6 with a peak wavelength of 480 nm, and the weight ratio of the red phosphor particles 8 and the blue phosphor particles 6 to colloid in the outer packaging layer 5 can be 1:100.

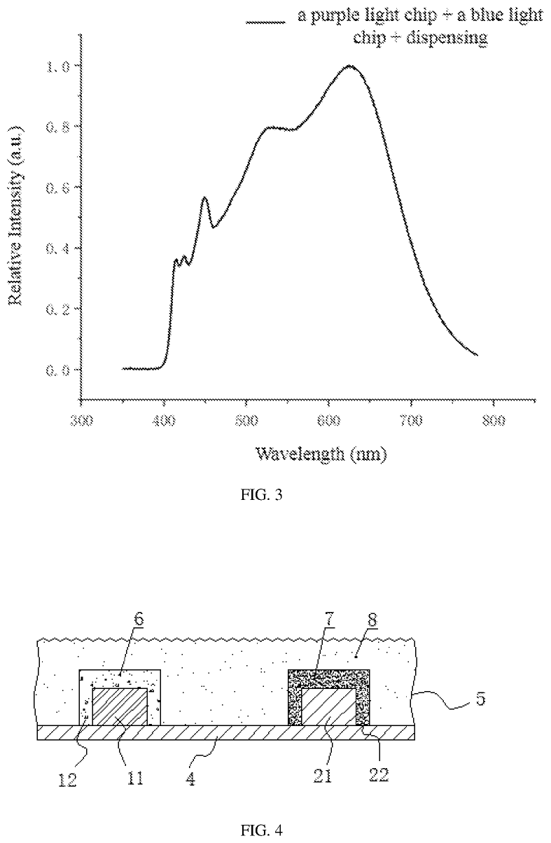

FIG. 3 is a spectrogram of the spectrum packaging structure in the present embodiment. It can be seen from the FIG. 3 that when a ratio of a weight of the red phosphor particles 8 in the outer packaging layer 5 to a total weight of the red phosphor particles 8 in the second packaging layer 22 and the red phosphor particles 8 in the outer packaging layer 5 is 70%, light efficiency of an overall package structure is 83.49 (lm/W). Compared with a conventional technical solution, dips in the spectrum between 470 nm to 480 nm can be significantly reduced, and the peak value of the purple light can be significantly reduced.

### Embodiment 2

The spectrum packaging structure of the present embodiment 2 is basically the same as that of the embodiment 1. As shown in FIG. 4, the spectrum packaging structure can include a substrate 4, an outer packaging layer 5, a first CSP chip 1, a second CSP chip 2, blue phosphor particles 6, yellow-green phosphor particles 7, and red phosphor particles 8. The first CSP chip 1 can be disposed on a substrate 4. The first CSP chip 1 can include a purple light chip 11 and a first packaging layer 12 coating an outer surface of the purple light chip 11. The second CSP chip 2 can be disposed on the substrate 4. The second CSP chip 2 can include a blue light chip 21 and a second packaging layer 22 coating an outer surface of the blue light chip 21. And the outer packaging layer 5 can be configured for packaging the first CSP chip 1 and the second CSP chip 2 on the substrate 4 in total.

A refractive index of the first packaging layer 12 is defined as n1, a refractive index of the second packaging layer 22 is defined as n2, a refractive index of the outer packaging layer 5 is defined as n3, and n1, n2, and n3 satisfy the following formula: n3≥n1>n2.

Yellow-green phosphor particles 7 can be only located in the second packaging layer 22.

Blue phosphor particles 6 can be located both in the first packaging layer 12 and the outer packaging layer 5. A ratio of a weight of the blue phosphor particles 6 in the first packaging layer 12 to a total weight of the blue phosphor particles 6 in the first packaging layer 12 and the blue phosphor particles 6 in the outer packaging layer 5 can be 70%, and a ratio of a weight of the blue phosphor particles 6 in the outer packaging layer 5 to a total weight of the blue phosphor particles 6 in the first packaging layer 12 and the blue phosphor particles 6 in the outer packaging layer 5 can be 30%.

Red phosphor particles 8 can be located both in the outer packaging layer 5 and the second packaging layer 22.

The difference between the embodiment 2 and embodiment 1 is that in the present embodiment 2, the top surface of the outer packaging layer 5 can be provided with microstructures. A ratio of a weight of the red phosphor particles 8 in the outer packaging layer 5 to a total weight of the red phosphor particles 8 in the second packaging layer 22 and the red phosphor particles 8 in the outer packaging layer 5 can be 30%, and a ratio of a weight of the red phosphor particles 8 in the second packaging layer 22 to a total weight of the red phosphor particles 8 in the second packaging layer 22 and the red phosphor particles 8 in the outer packaging layer 5 can be 70%.

In the present embodiment, a peak wavelength of the purple light chip 11 can be in a range of 390 nm to 420 nm, a peak wavelength of the blue light chip 21 can be 452 nm. A peak wavelength of the blue phosphor particles 6 can be 480 nm, and a peak wavelength of the yellow-green phosphor particles 7 can be 555 nm. A peak wavelength of the red phosphor particles 8 in the outer packaging layer 5 can be 660 nm, and a peak wavelength of the red phosphor particles 8 in the second packaging layer 22 can be 660 nm.

In the present embodiment, the first CSP chip 1 can be a purple light chip 11 with a size of 10 mil * 21 mil and a wavelength in a range of 407 nm to 412 nm. The blue phosphor particles 6 can be fluorescent powder with a peak wavelength of 480 nm, a weight ratio of the blue phosphor particles 6 to colloid in the first packaging layer 12 can be 3.5:1, colloid can include silica gel, and a refractive index n1 of silica gel can be 1.54.

The second CSP chip 2 can be a blue light chip 21 with a size of 13 mil * 30 mil and a peak wavelength in a range of 452.5 nm to 455 nm. The second packaging layer 22 can be a phosphor layer containing the yellow-green phosphor particles 7 with a peak wavelength of 565 nm and the red phosphor particles 8 with a peak wavelength of 660 nm. The weight ratio of the yellow-green phosphor particles 7 and the red phosphor particles 8 to silica gel in the second packaging layer 22 can be 13:1, and a refractive index n2 of the silica gel can be 1.42.

A refractive index n3 of silica gel of the outer packaging layer 5 can be 1.54. The outer packaging layer 5 can be a phosphor layer containing the red phosphor particles 8 with a peak wavelength of 660 nm and the blue phosphor particles 6 with a peak wavelength of 480 nm, and the weight ratio of the red phosphor particles 8, and the blue phosphor particles 6 to the silica gel in the outer packaging layer 5 can be 1:160.

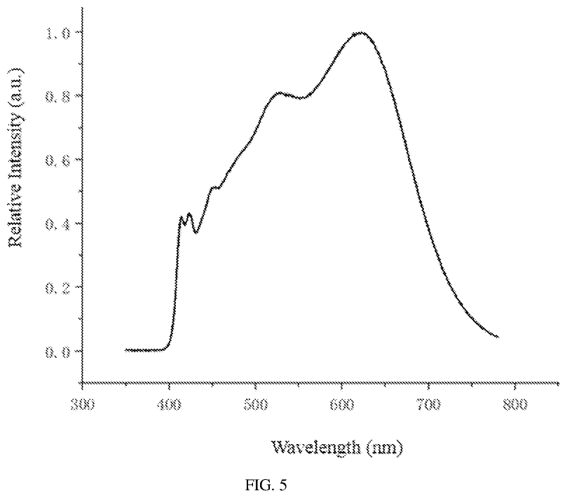

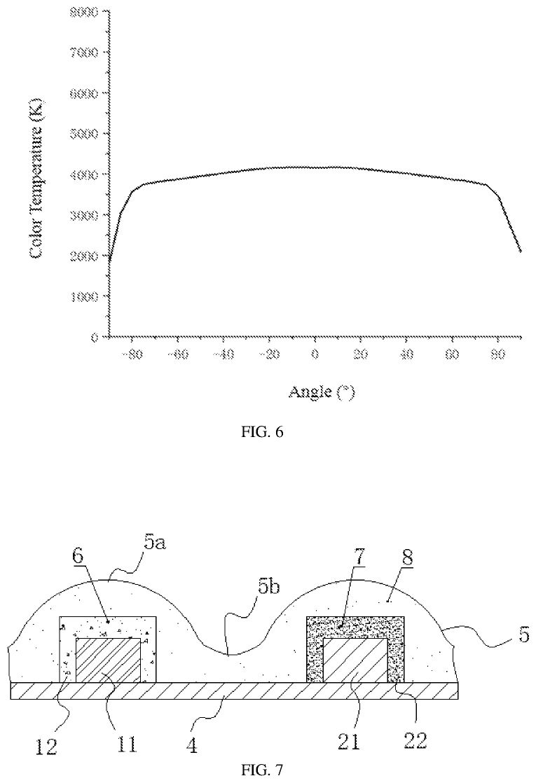

FIG. 5 is a spectrogram of the spectrum packaging structure in the present embodiment, and FIG. 6 is a spatial distribution diagram of color temperature of the spectrum packaging structure in the present embodiment. Advantages can be seen from the FIG. 5 to FIG. 6 that when most of the red phosphor particles 8 coating an outer surface of the blue light chip 21, absorption of short-wavelength purple light by the red phosphor particles 8 can be reduced. Light efficiency of an overall package structure is 81.13 (lm/W). It can be seen from the spectrum that the blue light of 480 nm can not be absorbed and there is no serious dip, and color temperature consistency of a light source is better.

### Embodiment 3

The spectrum packaging structure of the present embodiment is basically the same as that of the embodiment 2. As shown in FIG. 7, the spectrum packaging structure can include a substrate 4, an outer packaging layer 5, a first CSP chip 1, a second CSP chip 2, blue phosphor particles 6, yellow-green phosphor particles 7, and red phosphor particles 8.

Chip specifications and parameters used in the present embodiment are substantially the same as the embodiment 2. Peak wavelengths of blue phosphor particles 6, yellow-green phosphor particles 7, and red phosphor particles 8 are the same as the embodiment 2, and contents thereof in a first packaging layer 12, a second packaging layer 22, and an outer packaging layer 5 are the same as the embodiment 2.

The difference between the embodiment 3 and embodiment 2 is only that, in this embodiment 3, a top surface of the outer packaging layer 5 can be integrally formed with a plurality of arc-shaped protrusions 5a and a plurality of arc-shaped recesses 5b arranged at intervals. The plurality of arc-shaped protrusions 5a can be located directly above top surfaces of the first CSP chip 1 and the second CSP chip 2, and the plurality of arc-shaped recesses 5b can be located between the first CSP chip 1 and the second CSP chip 2 adjacent to the first CSP chip 1. The highest point of the plurality of arc-shaped protrusion 5a can be higher than the top surfaces of the first CSP chip 1 and the second CSP chip 2, and the lowest point of the plurality of arc-shaped recesses 5b can be lower than the top surfaces of the first CSP chip 1 and the second CSP chip 2. Projected contours of an outer surfaces of the arc-shaped protrusions 5a on the top surfaces of the first CSP chip 1 can completely cover and exceed edges of the top surfaces of the first CSP chip 1, and projected contours of an outer surfaces of the arc-shaped protrusions 5a on the top surfaces of the second CSP chip 2 can completely cover and exceed edges of the top surfaces of the second CSP chip 2.

In the present embodiment, a distance between the highest point of the plurality of arc-shaped protrusion 5a and the top surface of the first CSP chip 1 can be just greater than 40 micrometers, a distance between the highest point of the plurality of arc-shaped protrusion 5a and the top surface of the at least one second CSP chip 2 can be just greater than 40 micrometers. A distance between the lowest point of the plurality of arc-shaped recesses 5b and the top surface of the first CSP chip 1 can be just less than 80 micrometers, and a distance between the lowest point of the plurality of arc-shaped recesses 5b and the top surface of the at least one second CSP chip 2 can be just less than 80 micrometers.

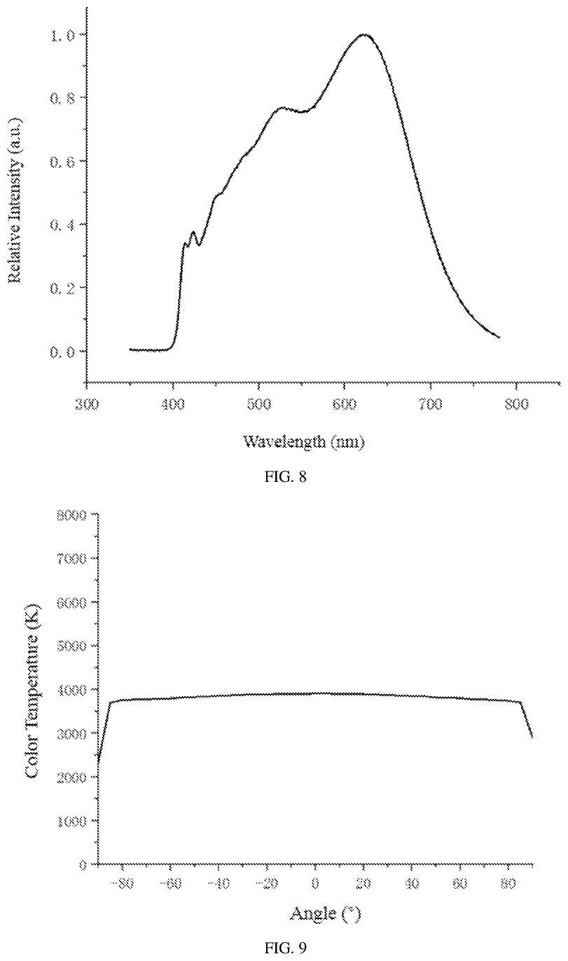

FIG. 8 is a spectrogram of the spectrum packaging structure in the present embodiment, and FIG. 9 is a spatial distribution diagram of color temperature of the spectrum packaging structure in the present embodiment.

It can be seen from the FIG. 8 to FIG. 9 that a wavy surface structure can reduce total reflection of the light and conducive to an exit of light beams, thereby improving light extraction efficiency of the spectrum packaging structure. Advantages can be seen that when most of the red phosphor particles 8 coating an outer surface of the blue light chip 21, absorption of purple light by the red phosphor particles 8 can be reduced. Light efficiency of an overall package structure is 89.96 (lm/W). It can be seen from the spectrum that the blue light of 480 nm can not be absorbed and there is no serious dip, and color temperature consistency of a light source is better.

### Embodiment 4

The spectrum packaging structure of the present embodiment is substantially the same as that of the embodiment 2. Chip specifications and parameters used in the present embodiment are exactly the same as the embodiment 3. Peak wavelengths of blue phosphor particles 6, yellow-green phosphor particles 7, and red phosphor particles 8 are the same as the embodiment 3. The difference is that the red phosphor particles 8 can not be located both in the outer packaging layer 5 and the second packaging layer 22, but can only be located in the second packaging layer 22, that is, the outer packaging layer 5 can only contain the blue phosphor particles.

### Embodiment 5

Referring to FIG. 11, the spectral packaging structure of this embodiment can be in a form of COB package and including:

ten first CSP chips 1 disposed on a substrate 4, wherein the first CSP chip 1 can include a purple light chip 11 and a first packaging layer 12 coating an outer surface of the purple light chip 11;

fifteen second CSP chips 2 disposed on the substrate 4, wherein the second CSP chip 2 can include a blue light chip 21 and a second packaging layer 22 coating an outer surface of the blue light chip 21; and

an outer packaging layer 5 for packaging the first CSP chip 1 and the second CSP chip 2 on the substrate 4 in total.

A plurality of blue phosphor particles 6, the blue phosphor particles 6 can only be located in the first packaging layer 12.

A plurality of yellow-green phosphor particles 7, the yellow-green phosphor particles 7 can only be located in the second packaging layer 22.

A plurality of red phosphor particles 8, the red phosphor particles 8 can be located both in the outer packaging layer 5 and the second packaging layer 22.

In the present embodiment, a peak wavelength of the purple light chip 11 can be in a range of 407 nm to 412 nm, a peak wavelength of the blue light chip 21 can be in a range of 452.5 nm to 455 nm. A peak wavelength of the blue phosphor particles 6 can be 480 nm, a peak wavelength of the yellow-green phosphor particles 7 can be 565 nm, and a peak wavelength of the red phosphor particles 8 can be 660 nm.

In the present embodiment, the yellow-green phosphor particles 7 can be located in the second packaging layer 22 of one of at least two second CSP chips 2, and the red phosphor particles 8 can be located in the second packaging layer 22 of the other of the at least two second CSP chips 2. The one of the at least two second CSP chips 2 including the second packaging layer 22 containing the red phosphor particles 8 can be disposed between the first CSP chip 1 and the other of the at least two second CSP chips 2 including the second packaging layer 22 containing the yellow-green phosphor particles 7, so as to block a pathway in which blue light excited by the purple light chip 11 in the first CSP chip 1 enter the second packaging layer 22 containing the yellow-green phosphor particles 7.

In the present embodiment, a refractive index of the first packaging layer 12 can be defined as n1, a refractive index of the second packaging layer 22 can be defined as n2. A refractive index of the second packaging layer 22a containing the yellow-green phosphor particles 7 can be denoted as n2a, a refractive index of the second packaging layer 22b containing the red phosphor particles 8 can be denoted as n2b, a refractive index of the outer packaging layer 5 can be defined as n3, and n1, n2a, n2b and n3 can satisfy the following formula: n3≥n1>n2a>n2b.

In the present embodiment, the first CSP chip 1 can be a purple light chip 11 with a size of 10 mil * 21 mil and a wavelength in a range of 407 nm to 412 nm, and a refractive index of the first packaging layer 12 can be 1.54. The blue phosphor particles 6 can be fluorescent powder with a peak wavelength of 480 nm, a weight ratio of the blue phosphor particles 6 to colloid in the first packaging layer 12 can be 3.5:1, colloid can include silica gel, and a refractive index n1 of silica gel can be 1.54.

The second CSP chip 2 can be a blue light chip 21 with a size of 13 mil * 30 mil and a peak wavelength in a range of 452.5 nm to 455 nm. The second packaging layer 22 can be a phosphor layer containing the yellow-green phosphor particles 7 with a peak wavelength of 565 nm and the red phosphor particles 8 with a peak wavelength of 660 nm.

The weight ratio of phosphor particles to colloid in the second packaging layer 22a containing the yellow-green phosphor particles 7 can be 10:1, and a refractive index n2a of the silica gel can be 1.42.

The weight ratio of phosphor particles to colloid in the second packaging layer 22b containing the red phosphor particles 8 can be 12:1, and a refractive index n2b of the silica gel can be 1.40.

A refractive index n3 of silica gel of the outer packaging layer 5 can be 1.54. The outer packaging layer 5 can be a phosphor layer containing the red phosphor particles 8 with a peak wavelength of 660 nm, and the blue phosphor particles 6 to the silica gel in the outer packaging layer 5 can be 1:130.

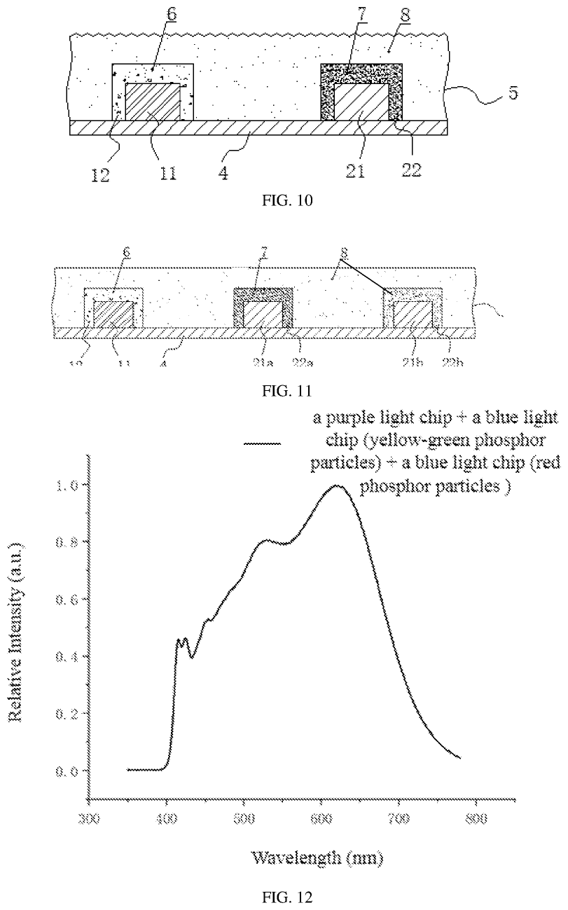

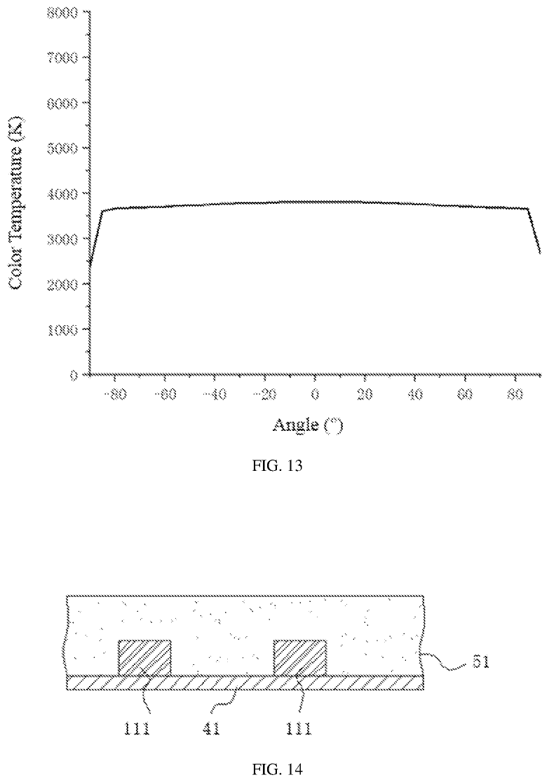

FIG. 12 is a spectrogram of the spectrum packaging structure in the present embodiment, and FIG. 13 is a spatial distribution diagram of color temperature of the spectrum packaging structure in the present embodiment. Advantages can be seen from FIG. 12 to FIG. 13 that that when most of the red phosphor particles 8 coating an outer surface of the blue light chip 21, absorption of purple light by the red phosphor particles 8 can be reduced. Light efficiency of an overall package structure is 95.51 (lm/W). It can be seen from the spectrum that the blue light of 480 nm can not be absorbed and there is no serious dip, and color temperature consistency of a light source is better.

### Comparative Example 1

A spectrum packaging structure of comparative example 1 is provided. Referring to FIG. 14, the spectrum packaging structure can include a substrate 41, and two purple light chips 111 disposed on the substrate 41, and an outer packaging layer 51 for packaging the two purple light chips 111 can be disposed outside the two purple light chips 111. Blue phosphor particles 61, yellow-green phosphor particles 71, and red phosphor particles 81 can be all located in the outer packaging layer 51. A peak wavelength of the purple light chip 111 can be in a range 390 nm to 420 nm, and the peak wavelengths of the blue phosphor particles 61, the yellow-green phosphor particles 71, and the red phosphor particles 81 are 480 nm, 602 nm, and 660 nm, respectively.

In the present example, the purple light chip 111 can be in a size of 10 mil * 21 mil and a wavelength in a range of 407 nm to 412 nm. The outer packaging layer 51 can be a phosphor layer containing the blue phosphor particles 61 with a peak wavelength of 480 nm, the yellow-green phosphor particles 71 with a peak wavelength of 565 nm and the red phosphor particles 81 with a peak wavelength of 660 nm. A weight ratio of the blue phosphor particles 61, the yellow-green phosphor particles 71 and red phosphor particles 81 to silica gel in the outer packaging layer 51 can be 3:16, and a refractive index n1 of silica gel can be 1.54.

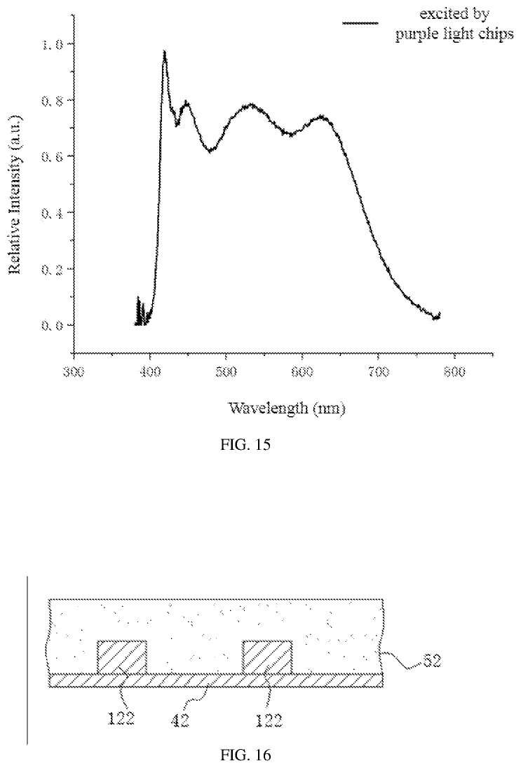

It can be seen from FIG. 14 to FIG. 15 that short-wavelength fluorescence excited by short-wavelength fluorescent powder can excite long-wavelength fluorescent powder again, long-wavelength fluorescence excited by the long-wavelength fluorescent powder can be reabsorbed, that is, there is a problem of secondary absorption of blue fluorescence and green fluorescence by the red phosphor particles 8, so that light efficiency of an overall package structure is 53.38 (lm/W), which is relatively low. At the same time, spectral components are not full, and spectral missing is serious.

### Comparative Example 2

A spectrum packaging structure of comparative example 2 is provided. Referring to FIG. 16, the spectrum packaging structure can include a substrate 42, and two blue light chips 212 disposed on the substrate 42, and an outer packaging layer 52 for packaging the two blue light chips 212 can be disposed outside the two blue light chips 212. Blue phosphor particles 62, yellow-green phosphor particles 72, and red phosphor particles 82 can be all located in the outer packaging layer 52. A peak wavelength of the blue light chip 212 can be in a range 390 nm to 420 nm, and the peak wavelengths of the blue phosphor particles 62, the yellow-green phosphor particles 72, and the red phosphor particles 82 are 480 nm, 565 nm, and 660 nm, respectively.

In the present example, the blue light chip 212 can be in a size of 13 mil * 30 mil and a wavelength in a range of 452.5 nm to 455 nm. The outer packaging layer 52 can be a phosphor layer containing the blue phosphor particles 62 with a peak wavelength of 480 nm, the yellow-green phosphor particles 72 with a peak wavelength of 565 nm and the red phosphor particles 82 with a peak wavelength of 660 nm. A weight ratio of the blue phosphor particles 62, the yellow-green phosphor particles 72 and red phosphor particles 82 to silica gel in the outer packaging layer 52 can be 3:16, and a refractive index n1 of silica gel can be 1.54.

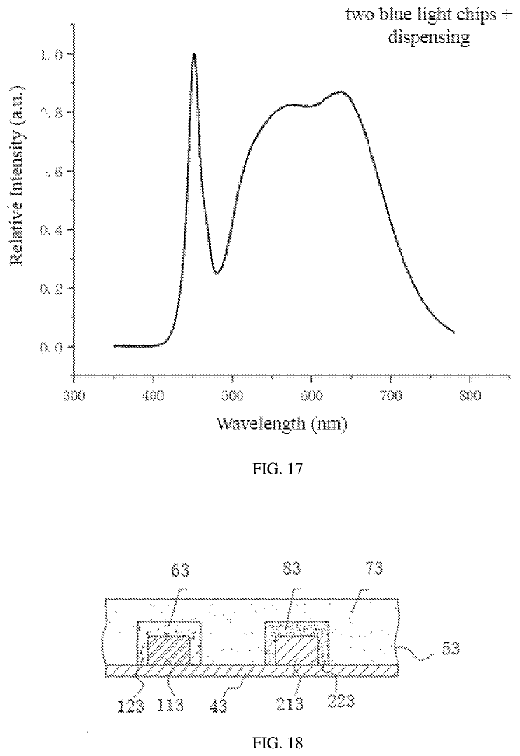

As shown in FIG. 17, although luminous efficiency of using the blue light chip 212 to excite mixed phosphor powder is 98.48 (lm/W), the excitation efficiency of the blue light chip 212 for the blue phosphor particles 62 can be extremely low, and blue light and yellow-green light excited by the blue light chip 212 can also be absorbed by the red phosphor particles 82, resulting in serious missing of spectral components, especially spectrum near 480 nm.

### Comparative Example 3

Referring to FIG. 18, the present comparative example 3 provides a spectrum packaging structure, including:

a substrate 43;

a luminous body arranged on the substrate 43, wherein the substrate 43 is configured for supporting or connected to the luminous body, and the luminous body can include a first CSP chip and at least one second CSP chip; and

an outer packaging layer 53 for packaging the luminous body on the substrate 43 in total or partially.

The spectrum packaging structure can further include a plurality of blue phosphor particles 63, a plurality of yellow-green phosphor particles 73, and a plurality of red phosphor particles 83.

The blue phosphor particles 63 can only be located in the first packaging layer 123.

The yellow-green phosphor particles 73 can only be located in the second packaging layer 223.

The red phosphor particles 83 can only be located in the second packaging layer 223.

In the present example, the first CSP chip can be a purple light chip with a size of 10 mil * 21 mil and a wavelength in a range of 407 nm to 412 nm, and a refractive index of the first packaging layer can be 1.54. A peak wavelength of the blue phosphor particles 63 can be 480 nm, a weight ratio of the blue phosphor particles 63 to colloid in the first packaging layer 123 can be 3.5:1, colloid can include silica gel, and a refractive index n1 of silica gel can be 1.54.

The second CSP chip can be a blue light chip 21 with a size of 13 mil * 30 mil and a peak wavelength in a range of 452.5 nm to 455 nm. The second packaging layer 223 can be a phosphor layer containing the red phosphor particles 83 with a peak wavelength of 660 nm. A weight ratio of the red phosphor particles 83 to the silica gel in the second packaging layer 223 can be 10:1, and the refractive index n2 of silica gel can be 1.42.

A refractive index n3 of silica gel of the outer packaging layer 53 can be 1.54. The outer packaging layer 53 can be a phosphor layer containing the yellow-green phosphor particles 73 with a peak wavelength of 565 nm, and the yellow-green phosphor particles 73 to the colloid in the outer packaging layer 53 can be 1:120.

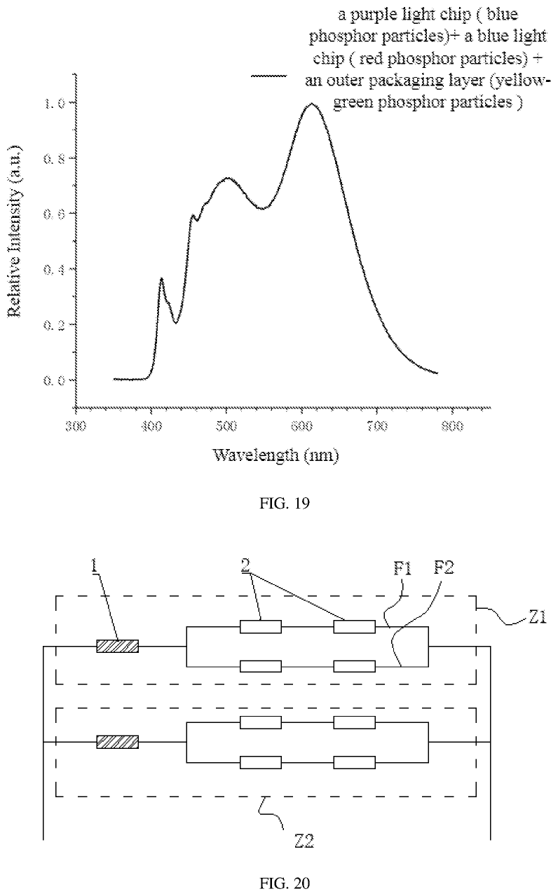

As shown in FIG. 19, although upon a condition that the purple light chip is used to excite the blue phosphor particles 63, the blue light chip 213 is used to excite the red phosphor particles 83, and then the yellow-green phosphor particles 73 is disposed in the outer packaging layer 53, luminous efficiency can be 80.12 (lm/W), the yellow-green phosphor particles 73 in the outer packaging layer 53 can absorb blue light with short wavelengths such as 450 nm and blue light with long wavelengths such as 480 nm, there are some dips in the spectrum of 480 nm.

A second implementation route that can coexist or be used in combination with the first implementation route of the present disclosure is further provided.

### Embodiment 6

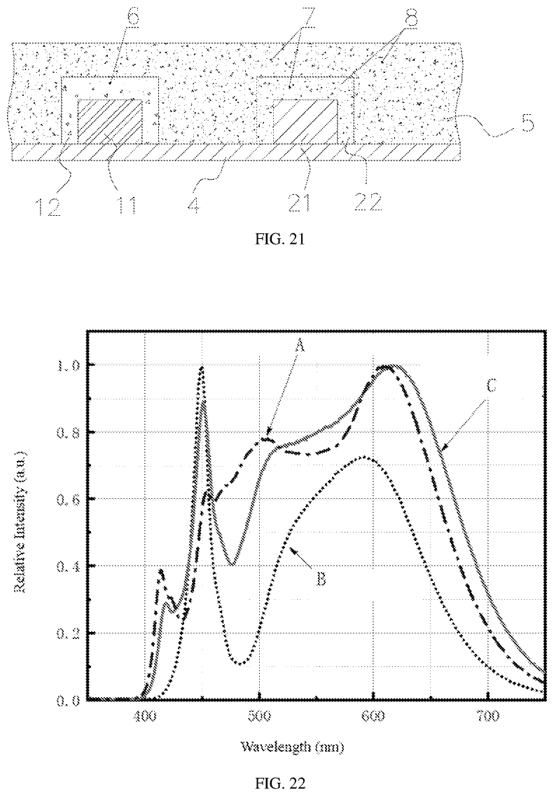

Referring to FIG. 21, an outer packaging layer 5 can be a phosphor layer containing red phosphor particles 8 and yellow-green phosphor particles 7. In this way, both the second packaging layer 22 and the outer packaging layer 5 can contain the red phosphor particles 8 and the yellow-green phosphor particles 7 to meet spectral requirements of a solar-like spectrum. However, considering a difference in absorption efficiency of blue light with different wavelengths light, in order to avoid the secondary excitation of other phosphor particles whose emission wavelengths are longer than the blue light caused by the blue light emitted from the blue phosphor particles 6 excited by the purple light chip 21, the following preferred technical solutions can be adopted.

Since a peak wavelength of the red phosphor particles 8 is greater than the peak wavelength of the yellow-green phosphor particles (one or both of yellow phosphor particles and green phosphor particles), most of the red phosphor particles 8 should be located in the second packaging layer 22 as much as possible, and most of the yellow-green phosphor particles 7 should be located in the outer packaging layer 5 as much as possible.

Since the red phosphor particles 8 and the yellow-green phosphor particles 7 are in different wavelengths, the red phosphor particles 8 and the yellow-green phosphor particles 7 with longer peak wavelengths can be chosen to be located in the second packaging layer 22, the red phosphor particles 8 and the yellow-green phosphor particles 7 with shorter peak wavelengths can be chosen to be located in the outer packaging layer 5.

Specifically, the red phosphor particles 8 located in the second packaging layer 22 can be long-wavelength red fluorescent powder with the peak wavelengths greater than 640 nm, and the yellow-green phosphor particles 7 located in the second packaging layer 22 can be long-wavelength yellow-green fluorescent powder with the peak wavelengths greater than 540 nm.

The red phosphor particles 8 located in the outer packaging layer 5 can be short-wavelength red fluorescent powder with the peak wavelengths less than 640 nm, and the yellow-green phosphor particles 7 located in the outer packaging layer 5 can be short-wavelength yellow-green fluorescent powder with the peak wavelengths less than 540 nm.

The peak wavelength of the long-wavelength red fluorescent powder in the second packaging layer 22 is greater than the peak wavelength of the short-wavelength red fluorescent powder in the outer packaging layer 5, and the peak wavelength of the long-wavelength yellow-green fluorescent powder in the second packaging layer 22 is greater than the peak wavelength of short-wavelength yellow-green fluorescent powder in the outer packaging layer 5.

Furthermore, a ratio of a weight of the long-wavelength red fluorescent powder in the second packaging layer 22 to a total weight of the fluorescent powder in the second packaging layer 22 can be more than 70%, and a ratio of a weight of the short-wavelength red fluorescent powder in the outer packaging layer 5 to a total weight of the fluorescent powder in the outer packaging layer 5 can be less than 30%.

The present disclosure further provides a method for manufacturing the spectrum packaging structure mentioned above, and the method mainly can include the following steps.

Step (1), preparing the luminous body, including the following sub-steps:

preparing the first CSP chip 1, wherein the first CSP chip 1 can include the purple light chip 11 and the first packaging layer 12 coating the outer surface of the purple light chip, the first packaging layer can include blue phosphor particles; and

preparing the at least one second CSP chip, wherein the at least one second CSP chip can include the blue light chip and the second packaging layer coating the outer surface of the blue light chip, the second packaging layer can include red phosphor particles and/or yellow-green phosphor particles.

Step (2), pre-controlling a color temperature of the luminous body, including the following sub-steps:

fixing the first CSP chip and the at least one second CSP chip to corresponding positions of the substrate;

turning on the first CSP chip to obtain a color dot position on a CIE chromaticity diagram, which is denoted as dot A (X1; Y 1);

turning on the at least one second CSP chip to obtain a color dot position or a mixed color dot position on the CIE chromaticity diagram, which is denoted as dot B (X2; Y2); and

turning on the first CSP chip and the at least one second CSP chip to obtain a mixed color dot position on the CIE chromaticity diagram, which is denoted as dot C (X3; Y3);

Step (3), preparing the outer packaging layer including:

coating the outer packaging layer on a surface of the substrate, and adjusting a ratio and/or peak wavelengths of each phosphor particle in the outer packaging layer to make a color dot position of the obtained spectrum packaging structure on the CIE chromaticity diagram coincide with a target color dot position, wherein the target color dot position is denoted as a dot D (X4; Y4).

The step (3) of preparing the outer packaging layer can include sub-step (3a) and sub-step (3b).

Sub-step (3a), according to color temperature requirement of the target spectrum packaging structure, searching for the target color dot position corresponding to the color temperature requirement on the CIE chromaticity diagram, and denoting the target color dot position as the dot D (X4;Y4); and

obtaining a specific coordinate value or a coordinate range of a color dot position of dot E (X5; Y5) on the CIE chromaticity diagram by using the dot C (X3; Y3) and the dot D (X4; Y4).

Sub-step (3b), adding the blue phosphor particles, the red phosphor particles and/or the yellow-green phosphor particles to a packaging material of the outer packaging layer; and

adjusting a ratio and/or peak wavelengths of the blue phosphor particles, the red phosphor particles, and/or the yellow-green phosphor particles to prepare the outer packaging layer according to a specific coordinate value or a coordinate range of a color dot position of dot E (X5; Y5).

If the blue phosphor particles are added in the packaging material of the outer packaging layer, determining whether the specific coordinate value or the coordinate range of the dot E (X5; Y5) falls within a color coordinate range corresponding to a range of peak wavelength of the blue phosphor particles firstly, and when if it is not within the color coordinate range corresponding to the range of peak wavelength of the blue phosphor particles, adjusting peak wavelengths and a weight ratio of various phosphor particles of the first packaging layer according to the dot A (X1; Y1) and the dot B (X2; Y2); and repeating sub-step (3a) until the specific coordinate value or the coordinate range of the dot E (X5; Y5) falls within the color coordinate range corresponding to the range of peak wavelength of the blue phosphor particles.

If the red phosphor particles are added in the packaging material of the outer packaging layer, determining whether the specific coordinate value or the coordinate range of the dot E (X5; Y5) falls within a color coordinate range corresponding to a range of peak wavelength of the red phosphor particles firstly, and when if it is not within the color coordinate range corresponding to the range of peak wavelength of the red phosphor particles, adjusting peak wavelengths and a weight ratio of various phosphor particles of the first packaging layer according to the dot A (X1; Y1) and the dot B (X2; Y2); and repeating sub-step (3a) until the specific coordinate value or the coordinate range of the dot E (X5; Y5) falls within the color coordinate range corresponding to the range of peak wavelength of the red phosphor particles.

Step (4), testing.

The following table is specification parameters of many batches of adopting the above-mentioned method to manufacture the spectrum packaging structure 100 in embodiment 6.

| | | a first | a second | a third | a fourth |
|---|---|---|---|---|---|
| | | batch | batch | batch | batch |
| purple light chip specification | | 1021 | 1021 | 1021 | 1021 |
| peak wavelength of the blue | | 480 | 480 | 480 | 480 |
| phosphor particles/nm | | | | | |
| blue light chip specification | | 1430 | 1430 | 1430 | 1430 |
| second | peak wavelength of | 650 | 650 | 660 | 660 |
| packaging | the red phosphor | | | | |
| layer | particles/nm | | | | |
| | W₁ | 80% | 80% | 70% | 70% |
| | peak wavelength of | 550 | 540 | 550 | 540 |
| | the yellow-green | | | | |
| | phosphor particles/nm | | | | |
| | W₂ | 20% | 20% | 30% | 30% |
| outer | peak wavelength of | 600 | 620 | 620 | 640 |
| packaging | the red phosphor | | | | |
| layer | particles/nm | | | | |
| | W₃ | 30% | 25% | 20% | 20% |
| | peak wavelength of | 505 | 520 | 520 | 540 |
| | the yellow-green | | | | |
| | phosphor particles/nm | | | | |
| | W₄ | 70% | 75% | 80% | 80% |

In the table above, W₁ is defined as a ratio of a weight of the red fluorescent powder 8 in the second packaging layer 22 to a total weight of the fluorescent powder in the second packaging layer 22; W₂ is defined as a ratio of a weight of the yellow-green phosphor particles 7 in the second packaging layer 22 to a total weight of the fluorescent powder in the second packaging layer 22; W₃ is defined as a ratio of a weight of the red fluorescent powder 8 in the outer packaging layer 5 to a total weight of the fluorescent powder in the outer packaging layer 5; and W₄ is defined as a ratio of a weight of the yellow-green phosphor particles 7 in the outer packaging layer 5 to a total weight of the yellow-green phosphor particles 7 in the outer packaging layer 5.

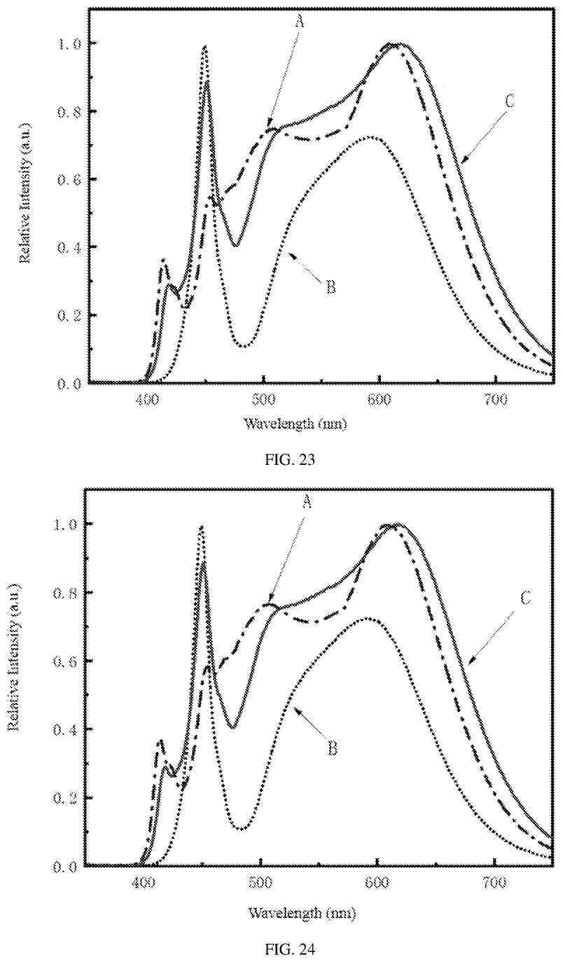

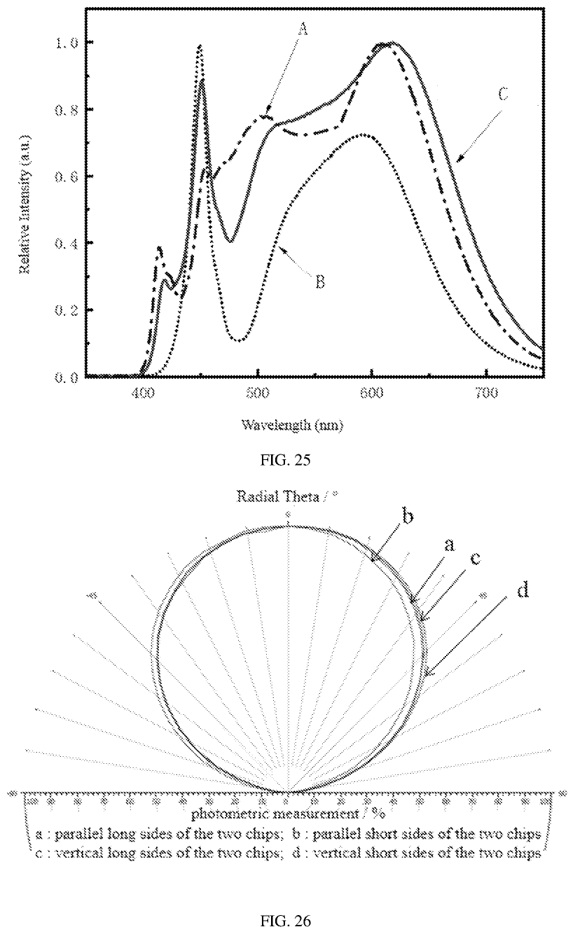

FIG. 22 to FIG. 25 is a comparison of spectrograms obtained by each batch of the solar-like spectrum packaging structure of the present disclosure (C), conventional blue light chip excitation (A), and conventional purple light chip exciting the blue phosphor particles 6 superimposed conventional blue light chip excitation (B).

From spectral test data above, it can be seen that, the method for manufacturing the spectrum packaging structure of the present embodiment can effectively make up and improve problems of absence of spectrum near 480 nm or low intensity, which can exist in the conventional blue light chip excitation and the conventional purple light chip exciting the blue phosphor particles 6 superimposed conventional blue light chip excitation. At the same time, the spatial angle distribution of light source is more uniform, and color uniformity and saturation are higher.

FIG. 26 is a distribution diagram of light-exiting angles of a first batch of a solar-like spectrum packaging structure. From test data of the light-exiting angles above, it can be seen that, by using the method in the present embodiment, the spatial angle of the light source can reach more than 120 degrees, and the spatial angle distribution can be more uniform.

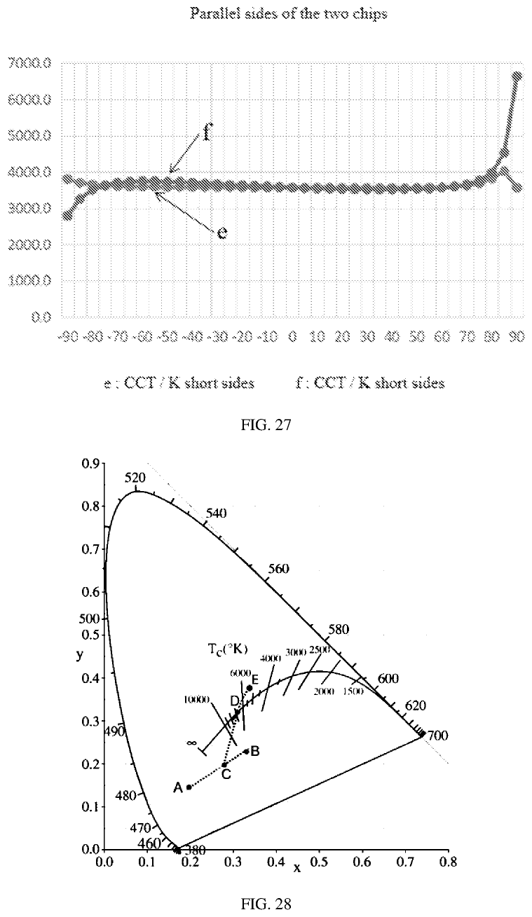

FIG. 27 is test data of a color temperature uniformity test diagram of the first batch of the spectrum packaging structure. It can be seen from the test data that the light source of the present embodiment is more uniform and more consistent in color temperature distribution.

We claim:

1. A spectrum packaging structure, comprising:
a substrate;
a luminous body arranged on the substrate, wherein the substrate is configured for supporting or connected to the luminous body, and the luminous body comprises a first CSP chip and at least one second CSP chip; and
an outer packaging layer for packaging the luminous body on the substrate in total or partially,
wherein the first CSP chip comprises a purple light chip and a first packaging layer coating an outer surface of the purple light chip, the first packaging layer is a phosphor layer containing blue phosphor particles,
the at least one second CSP chip comprises a blue light chip and a second packaging layer coating an outer surface of the blue light chip, the second packaging layer is a phosphor layer containing red phosphor particles and/or yellow-green phosphor particles.

2. The spectrum packaging structure of claim 1, wherein a refractive index of the first packaging layer is defined as n₁, a refractive index of the second packaging layer is defined as n₂, a refractive index of the outer packaging layer is defined as n₃, and n₁, n₂, and n₃ satisfy the following formula: n₃≥n₁>n₂.

3. The spectrum packaging structure of claim 1, wherein a peak wavelength of the blue light chip is in a range of 430 nm to 460 nm, and a peak wavelength of the purple light chip is in a range of 390 nm to 420 nm.

4. The spectrum packaging structure of claim 1, the outer packaging layer further comprises blue phosphor particles.

5. The spectrum packaging structure of claim 1, wherein the outer packaging layer further comprises red phosphor particles, a ratio of a weight of the red phosphor particles in the second packaging layer to a total weight of the red phosphor particles in the second packaging layer and the red phosphor particles in the outer packaging layer is in a range of 50% to 80%.

6. The spectrum packaging structure of claim 1, wherein the luminous body comprises at least two second CSP chips, the red phosphor particles are located in the second packaging layer of one of the at least two second CSP chips, and the yellow-green phosphor particles are located in the second packaging layer of the other of the at least two second CSP chips.

7. The spectrum packaging structure of claim 6, wherein the one of the at least two second CSP chips comprising the second packaging layer containing the red phosphor particles is disposed between the first CSP chip and the other of the at least two second CSP chips comprising the second packaging layer containing the yellow-green phosphor particles.

8. The spectrum packaging structure of claim 1, wherein a top surface of the outer packaging layer is provided with a plurality of arc-shaped protrusions and a plurality of arc-shaped recesses arranged at intervals, the plurality of arc-shaped protrusions are located directly above top surfaces of the first CSP chip and the at least one second CSP chip, the plurality of arc-shaped recesses are located between the first CSP chip and the at least one second CSP chip adjacent to the first CSP chip, the highest point of the plurality of arc-shaped protrusion is not lower than the top surfaces of the first CSP chip and the at least one second CSP chip, and the lowest point of the plurality of arc-shaped recesses is not higher than the top surfaces of the first CSP chip and the at least one second CSP chip.

9. The spectrum packaging structure of claim 8, wherein a distance between the highest point of the plurality of arc-shaped protrusion and the top surface of the first CSP chip is greater than or equal to 40 micrometers, a distance between the highest point of the plurality of arc-shaped protrusion and the top surface of the at least one second CSP chip is greater than or equal to 40 micrometers, a distance between the lowest point of the plurality of arc-shaped recesses and the top surface of the first CSP chip is less than or equal to 80 micrometers, and a distance between the lowest point of the plurality of arc-shaped recesses and the top surface of the at least one second CSP chip is less than or equal to 80 micrometers.

10. The spectrum packaging structure of claim 1, wherein
the first CSP chip and the at least one second CSP chip are electrically connected to form a circuit, and the first CSP chip and the second CSP chip are connected in series;
when the circuit comprises a plurality of branches in a parallel connection, a total number of chips in each of the plurality of branches is the same, the number and a connection mode of the first CSP chip in each of the plurality of branches are the same, and the number and a connection mode of the at least one second CSP chip in each of the plurality of branches are the same.

11. The spectrum packaging structure of claim 1, wherein the outer packaging layer is a phosphor layer containing red phosphor particles and yellow-green phosphor particles.

12. The spectrum packaging structure of claim 1, wherein the red phosphor particles and the yellow-green phosphor particles in the second packaging layer are a long-wavelength red fluorescent powder and a long-wavelength yellow-green fluorescent powder, respectively, the red phosphor particles and the yellow-green phosphor particles in the outer packaging layer are a short-wavelength red fluorescent powder and a short-wavelength yellow-green fluorescent powder, respectively,
a peak wavelength of the long-wavelength red fluorescent powder of the second packaging layer is greater than a peak wavelength of the short-wavelength red fluorescent powder of the outer packaging layer,
a peak wavelength of the long-wavelength yellow-green fluorescent powder of the second packaging layer is greater than a peak wavelength of the short-wavelength yellow-green fluorescent powder of the outer packaging layer,
the peak wavelength of the long-wavelength red fluorescent powder of the second packaging layer is greater than 640 nm, the peak wavelength of the long-wavelength yellow-green fluorescent powder of the second packaging layer is greater than 540 nm, the peak wavelength of the short-wavelength yellow-green fluorescent powder of the outer packaging layer is less than 540 nm, and the peak wavelength of the short-wavelength red fluorescent powder of the outer packaging layer is less than 640 nm.

13. A method for manufacturing the spectrum packaging structure of claim 1, comprising:
step (1), preparing the luminous body, comprising the following sub-steps:
preparing the first CSP chip, wherein the first CSP chip comprises the purple light chip and the first packaging layer coating the outer surface of the purple light chip, the first packaging layer comprises blue phosphor particles; and
preparing the at least one second CSP chip, wherein the at least one second CSP chip comprises the blue light chip and the second packaging layer coating the outer surface of the blue light chip, the second packaging layer comprises red phosphor particles and/or yellow-green phosphor particles;
step (2), pre-controlling a color temperature of the luminous body, comprising the following sub-steps:
fixing the first CSP chip and the at least one second CSP chip to corresponding positions of the substrate;
turning on the first CSP chip to obtain a color dot position on a CIE chromaticity diagram, which is denoted as dot A (X1; Y 1);
turning on the at least one second CSP chip to obtain a color dot position or a mixed color dot position on the CIE chromaticity diagram, which is denoted as dot B (X2; Y2); and
turning on the first CSP chip and the at least one second CSP chip to obtain a mixed color dot position on the CIE chromaticity diagram, which is denoted as dot C (X3; Y3);
step (3), preparing the outer packaging layer comprising:
coating the outer packaging layer on a surface of the substrate, and adjusting a ratio and/or peak wavelengths of each phosphor particle in the outer packaging layer to make a color dot position of the obtained spectrum packaging structure on the CIE chromaticity diagram coincide with a target color dot position, wherein the target color dot position is denoted as a dot D (X4; Y4); and
step (4), testing.

14. The method of claim 13, wherein the step (3) of preparing the outer packaging layer comprises:
sub-step (3a), according to color temperature requirement of the target spectrum packaging structure, searching for the target color dot position corresponding to the color temperature requirement on Planck locus of the CIE chromaticity diagram, and denoting the target color dot position as the dot D (X4;Y4); and
obtaining a specific coordinate value or a coordinate range of a color dot position of dot E (X5; Y5) on the CIE chromaticity diagram by using the dot C (X3; Y3) and the dot D (X4; Y4); and
sub-step (3b), adding the blue phosphor particles, the red phosphor particles and/or the yellow-green phosphor particles to a packaging material of the outer packaging layer; and
adjusting a ratio and/or peak wavelengths of the blue phosphor particles, the red phosphor particles, and/or the yellow-green phosphor particles to prepare the outer packaging layer according to a specific coordinate value or a coordinate range of a color dot position of dot E (X5; Y5),
wherein if the blue phosphor particles are added in the packaging material of the outer packaging layer,
determining whether the specific coordinate value or the coordinate range of the dot E (X5; Y5) falls within a color coordinate range corresponding to a range of peak wavelength of the blue phosphor particles firstly, and
when if it is not within the color coordinate range corresponding to the range of peak wavelength of the blue phosphor particles, adjusting peak wavelengths and a weight ratio of various phosphor particles of the first packaging layer according to the dot A (X1; Y1) and the dot B (X2; Y2); and repeating sub-step (3a) until the specific coordinate value or the coordinate range of the dot E (X5; Y5) falls within the color coordinate range corresponding to the range of peak wavelength of the blue phosphor particles; and
if the red phosphor particles are added in the packaging material of the outer packaging layer,
determining whether the specific coordinate value or the coordinate range of the dot E (X5; Y5) falls within a color coordinate range corresponding to a range of peak wavelength of the red phosphor particles firstly, and
when if it is not within the color coordinate range corresponding to the range of peak wavelength of the red phosphor particles, adjusting peak wavelengths and a weight ratio of various phosphor particles of the first packaging layer according to the dot A (X1; Y1) and the dot B (X2; Y2); and repeating sub-step (3a) until the specific coordinate value or the coordinate range of the dot E (X5; Y5) falls within the color coordinate range corresponding to the range of peak wavelength of the red phosphor particles.
